(19) United States
(12) Patent Application Publication
(10) Pub. No.: US 2005/0000682 A1
(43) Pub. Date: Jan. 6, 2005

(54) Heat dissipating fins of heat sink and manufacturing method thereof

(76) Inventors: Chao-Nan Chien, Taoyuan Hsien (TW); Yu-Hung Huang, Taoyuan Hsien (TW); Chin-Ming Chen, Taoyuan Hsien (TW)

Correspondence Address: HARNESS, DICKEY & PIERCE, P.L.C., P.O. BOX 828, BLOOMFIELD HILLS, MI, 48303, US

(21) Appl. No.: 10/658,303

(22) Filed: Sep. 9, 2003

(30) Foreign Application Priority Data
Jul. 4, 2003 (TW) 92118255

(51) Int. Cl. H05K 7/20

(52) U.S. Cl. 165/80.3; 165/185

(57) ABSTRACT

A heat-dissipating fin of a heat sink for improving thermal conduction is disclosed. The heat sink has a base plate and a plurality of heat-dissipating fins. The base plate includes a first surface contacting with a heat source, and a second surface having a plurality of grooves orderly formed on the second surface. The heat dissipating fin of the heat sink has the feature that the thickness of the heat-dissipating fin is not uniform, and the thickness of a bottom surface of the heat-dissipating fin facing the groove is greater than the other portions of the heat-dissipating fin.

### FIELD OF THE INVENTION

The present invention relates to a heat sink, and more particularly, to the heat sink of which heat-dissipating fins are not uniform in thickness.

### BACKGROUND OF THE INVENTION

While the performance of an electronic device is enhanced, the heat-dissipating element or the heat-dissipating system has been an essential equipment in the current electronic devices. If the heat generated by the electronic device is not properly removed, the performance of the electronic device will be degraded, and what is worse, the electronic device may be burned. The heat-dissipating element is more important for micro electronic devices, such as integrated circuits, since with the increase of the component density and the improvement of the technology of packaging, the area of the integrated circuit decreases, and meanwhile, the heat in every unit square increases. Therefore, a rapid heat-dissipating element always plays an important role in electronic industrial fields.

Generally speaking, the heat sink has a heat-dissipating base plate and a plurality of heat-dissipating fins located on the heat-dissipating base plate. The heat sink is installed on the surface of the element to dissipate the heat generated. Most of the heat sinks are made by extrusion process. However, the height and thickness proportionality of heat-dissipating fins made by extrusion process are restricted by the current manufacturing techniques, and efficiency of heat-dissipating cannot be improved. Thus, the requirement of dissipating the heat greatly increased by current electronic devices cannot be satisfied. Besides, the heat-dissipating fins and the heat-dissipating base plate also can be jointed together by welding. However, after welding, thermal conductive resistance is increased on the welding surface between heat-dissipating fins and the heat-dissipating base plate, so that the demand of high thermal conduction cannot be met.

For resolving the above-identified problems, a conventional method is performed by laminating and pinning, thereby decreasing the thermal resistance between the heat-dissipating fins and the heat-dissipating base plate. Please refer to FIG. 1A and FIG. 1B. FIG. 1A is a schematic diagram sketching the structure of a conventional heat sink 10. FIG. 1B is a front view illustrating the heat sink 10 shown in FIG. 1A. As shown in FIG. 1A and FIG. 1B, the heat sink 10 disclosed by U.S. Pat. No. 6,554,060 includes a heat-dissipating base plate 12 and a plurality of heat-dissipating fins 14. A first surface of the heat-dissipating base plate 12 contacts with a heat source of which the heat is desired to be dissipated (not shown), and a plurality of grooves 16 are formed on a second surface by machining for inserting heat-dissipating fins 14. Then, the method of mechanical-punching is performed to press the second surface between every two heat-dissipating fins 14 located on the heat-dissipating base plate 12. Thus, because of the downward pressing force exerted on the second surface of the heat-dissipating base plate 12, the material can extend laterally so as to deform the shape of grooves 16, whereby a plurality of heat-dissipating fins 14 are fixed in the grooves 16. Consequently, the heat-dissipating base plate 12 and heat-dissipating fins 14 can be directly jointed so as to reduce the contact thermal resistance. Then, the heat coming from the heat source can be transferred to the heat-dissipating fins 14 directly via the heat-dissipating base plate 12.

However, there are still shortcomings in the aforementioned method. Please refer to FIG. 2A, FIG. 2B and FIG. 2C. FIG. 2A to FIG. 2C are schematic diagrams sketching the partial structure of the heat sink 10 shown in FIG. 1 while the heat-dissipating fins 14 are in combination with the heat-dissipating base plate 12. As shown in FIG. 2A and FIG. 2B, in order to fix the heat-dissipating fins 14 in the grooves 16 located on the heat-dissipating base plate 12, the conventional method is to form the grooves 16 on the second surface of the heat-dissipating base plate 12 with width L and depth H, and then the heat-dissipating fins 14 of which the thickness is less than width L are inserted in the grooves 16, and thereafter, both sides of the grooves 16 on the heat-dissipating base plate 12 are pressed by punching, such as the punching points a shown in FIG. 2A. Therefore, two punched-grooves 18 are formed on the punching points a located on both sides of the grooves 16 of the heat-dissipating base plate 12 thereby fixing the heat-dissipating fins 14 in the grooves 16, such as shown in FIG. 2B. Meanwhile, the heat-dissipating fins 14 and the heat-dissipating base plate 12 cannot have full surface contact, so that gaps 19 in the grooves 16 will be caused, thus increasing the conductive thermal resistance between the heat-dissipating base plate 12 and heat-dissipating fins 14.

Moreover, referring to FIG. 2C, while both sides of the groove 16 on the heat-dissipating base plate 12 are punched, vibration will be generated instantly in the punching process, and the gaps 19 are formed since bottom surfaces of the heat-dissipating fins 14 do not contact the grooves 16, thus increasing the conductive thermal resistance between the heat-dissipating base plate 12 and the heat-dissipating fins 14. The conditions described above all affect the heat-transfer efficiency of the heat sink 10.

### SUMMARY OF THE INVENTION

Hence, an object of the present invention is to provide a heat sink having heat-dissipating fins of non-uniform thickness, for making the heat-dissipating fins and the heat-dissipating base plate maintain tight contact after punching forming; increasing the contact area between the heat-dissipating fins and the heat-dissipating base plate; and effectively decreasing the conductive thermal resistance therebetween.

The heat sink of the present invention comprises a heat-dissipating base plate and a plurality of heat-dissipating fins. The heat-dissipating base plate has a first surface contacting a heat source, and a second surface having a plurality of grooves with predetermined widths and depths for inserting a plurality of heat-dissipating fins. The heat-dissipating fins of the heat sink are featured in that each of the heat-dissipating fins has non-uniform thickness, and the thickness of a bottom surface of each heat-dissipating fin facing the groove is greater than that of the other portions of each heat-dissipating fin.

According to the heat sink of the present invention having heat-dissipating fins with non-uniform thickness, not only the tight contact between the heat-dissipating fins and the heat-dissipating base plate can be maintained after punching forming, but also the contact area therebetween can be increased so as to decrease the conductive thermal resistance and enhance the performance of the heat sink on dissipating heat.

### BRIEF DESCRIPTION OF THE DRAWINGS

FIG. 1A is a schematic diagram illustrating the structure of a conventional heat sink;

FIG. 1B is a front view of a heat sink shown in FIG. 1;

FIG. 2A to FIG. 2C are the schematic diagram sketching the partial structure of the heat sink shown in FIG. 1 while heat-dissipating fins are in combination with the heat-dissipating base plate;

FIG. 3A is a schematic diagram illustrating the structure of the heat sink of the present invention;

FIG. 3B is a front view of a heat sink shown in FIG. 3A;

FIG. 4A and FIG. 4B are the schematic diagram sketching the partial structure of the heat sink shown in FIG. 3 while heat-dissipating fins are in combination with the heat-dissipating base plate; and

FIG. 4C is a schematic diagram sketching the partial structure of the heat sink according to the other embodiment of the present invention.

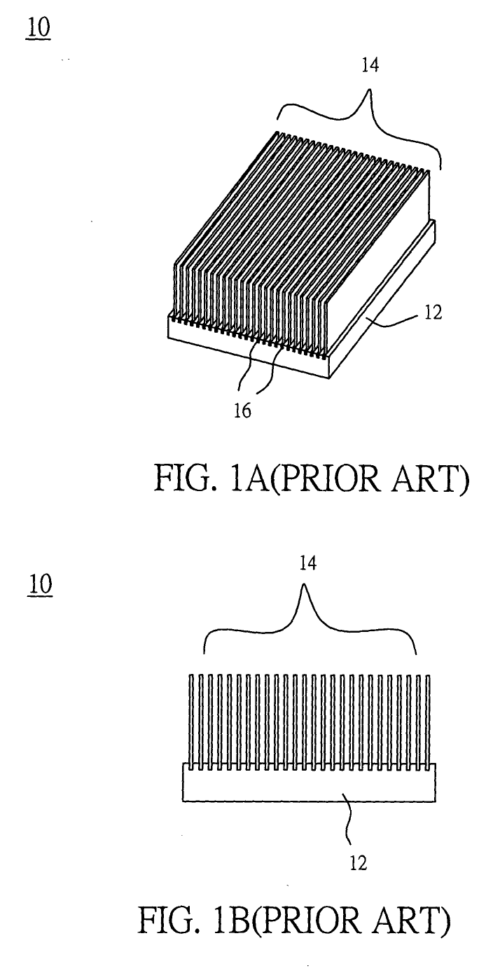

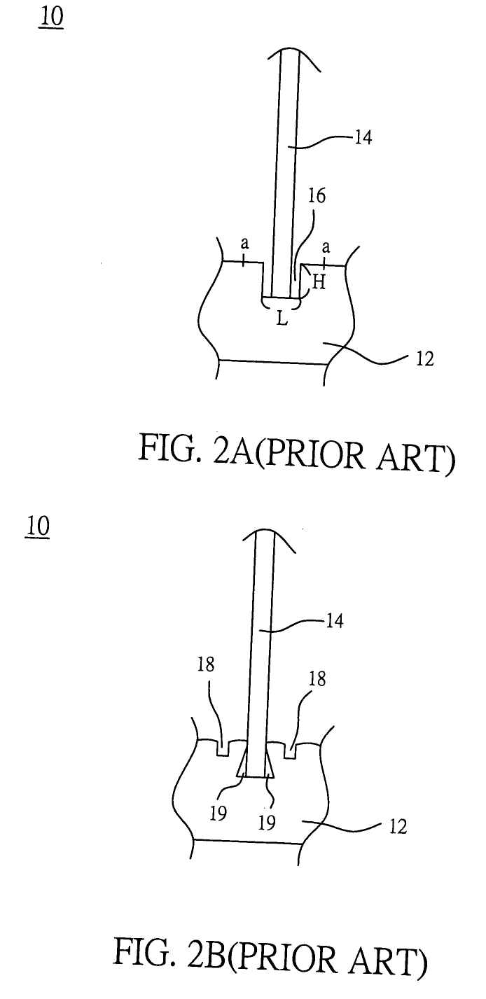

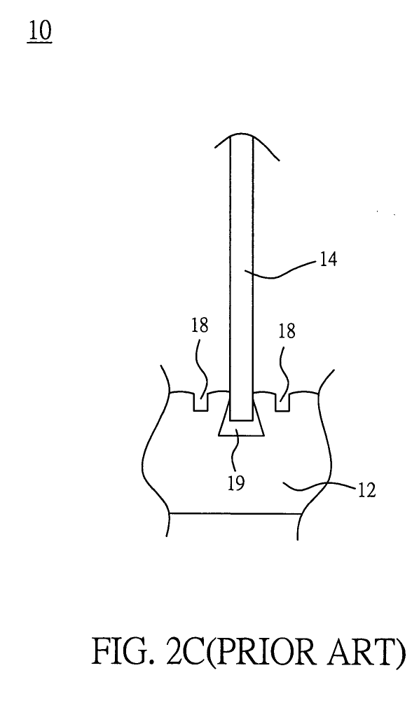

### DETAILED DESCRIPTION OF THE PREFERRED EMBODIMENT

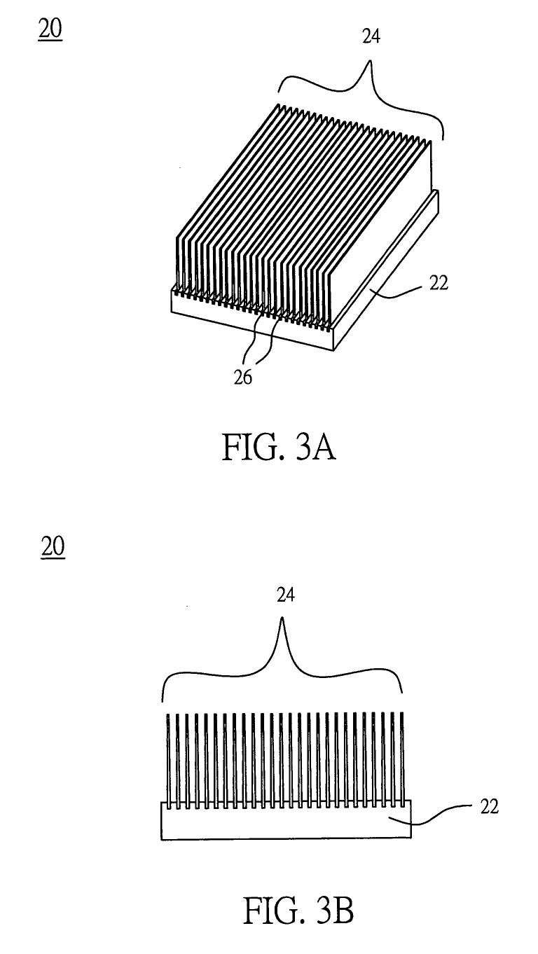

Please refer to FIG. 3A and FIG. 3B. FIG. 3A is a schematic diagram illustrating the structure of a heat sink 20 of the present invention. FIG. 3B is a front view of the heat sink 20 shown in FIG. 3A. Such as shown in FIG. 3A and FIG. 3B, the heat sink 20 of the present invention includes a heat-dissipating base plate 22 and a plurality of heat-dissipating fins 24. Since the heat-transfer property of copper is better, the heat-dissipating base plate 22 is made of the metal material selected from the group consisting of copper or copper alloys. A first surface of the heat-dissipating base plate 22 contacts with a heat source of which the heat is desired to be dissipated (not shown), and a plurality of grooves 26 with width L and depth H are formed on a second surface of the heat-dissipating base plate 22 by machining for inserting heat-dissipating fins 24. Furthermore, the heat-dissipating fins 24 are thin slices of the metal material selected from the group consisting of copper, copper alloys, aluminum or aluminum alloys.

The most distinct difference between the heat sink 20 of the present invention and a conventional heat sink 10 is that the heat-dissipating fins 24 of the heat sink 20 have non-uniform thickness and the shape of it is trapezoid. In other words, the thickness of a bottom surface of each heat-dissipating fin 24 is greater than that of the other portions of each heat-dissipating fin 24. Concretely speaking, the thickness of the bottom surface of the heat-dissipating fin 24 is approximate to the width L of the grooves 26.

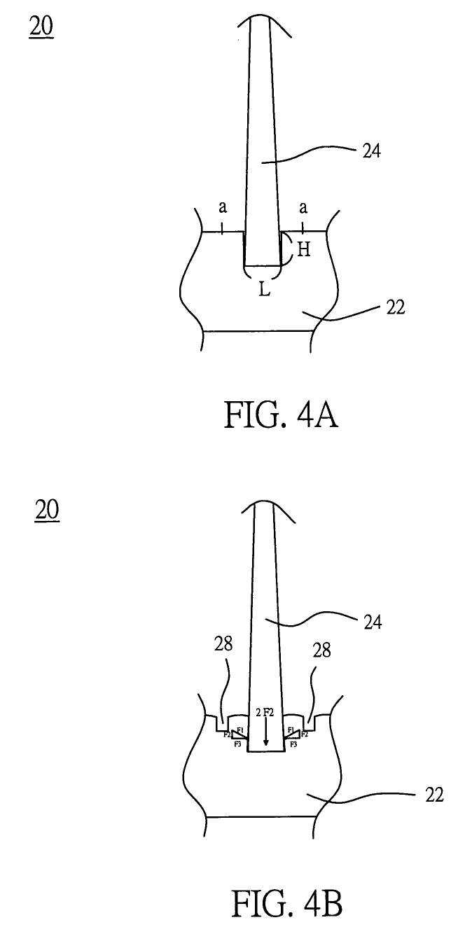

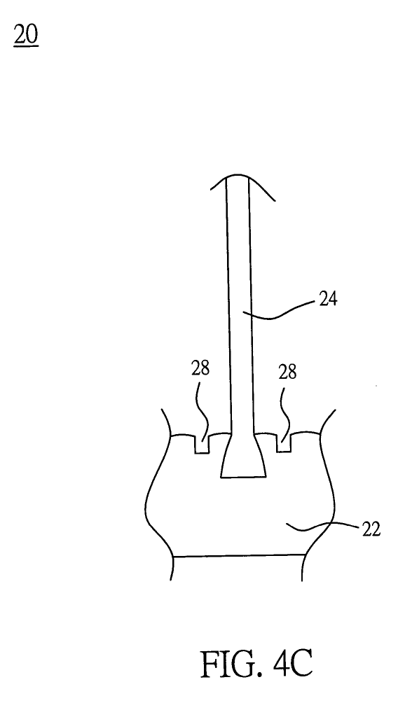

In order to more easily explain the manufacturing process of the heat sink 20 of the present invention, just some partial structures and figures of the heat sink 20 will be used to stand for the present invention. Please refer to FIG. 4A and FIG. 4B. FIG. 4A and FIG. 4B are the schematic diagram sketching the partial structure of the heat sink 20 shown in FIG. 3 while heat-dissipating fins 24 are in combination with the heat-dissipating base plate 22. Such as shown in FIG. 4A, while producing the heat sink 20 of the present invention, first choose a plurality of aforementioned heat-dissipating fins 24 to insert in every groove 26 on the heat sink 20. Meanwhile, the bottom surface of the heat-dissipating fin 24 and the bottom surface of the groove 26 cam be fully jointed together, but there is still gap between both sides of heat-dissipating fins 24 and those of grooves 26. Then, the method of mechanical-punching is performed to press the second surface between every two heat-dissipating fins 24 located on the heat-dissipating base plate 22, such as punching points a shown in FIG. 4A. Hence, two punched-grooves 28 are formed on the punching points a located on both sides of the grooves 26 of the heat-dissipating base plate 22, such as shown in FIG. 4B.

While two punched-grooves 28 are formed on the punching points a located on both sides of the grooves 26 of the heat-dissipating base plate 22, the material of both sides of the grooves 26 of the heat-dissipating base plate 22 will form two forces F1 by the pressing force in the punching process. Both sides of each of the grooves 26 and both sides of each of the heat-dissipating fins 24 will tightly jointed together because of the force F1. The horizontal component of force F3 of the two forces F1 will be offset. Meanwhile, the both sides of the grooves 26 will form two linear contact bevels with those of heat-dissipating fins 24. Therefore, there would hardly be gaps between heat-dissipating fins 24 and the heat-dissipating base plate 22 as gap 19 in the conventional heat sink 10. Furthermore, because of the same direction, the vertical component of force F2 of the two forces F1 will combine and form two downward forces to press the heat-dissipating fins 24, and it makes the bottom surface of the heat-dissipating fins 24 and that of the groove 26 jointed more tightly. Thereof, the gap between the heat-dissipating fins 24 and the groove 26 can be avoided forming for the vibration of the heat-dissipating fins 24 by the force during the punching process in the conventional method.

In order to increase the contact area of the heat-dissipating fins and the groove of the heat-dissipating base plate, furthermore, to enhance the performance of the heat sink, the contact area of the heat-dissipating fins and the groove of the heat sink of the present invention is not just linear contact area. Please refer to FIG. 4C. FIG. 4C is a schematic diagram sketching the partial structure of the heat sink 20 according to the other embodiment of the present invention. Such as shown in FIG. 4C, the most distinct difference between this embodiment and the aforementioned embodiment is that the both sides of the heat-dissipating fins 24 in the grooves 26 are not linear oblique bevels. That is, the both sides of the grooves 26 and those of the heat-dissipating fins 24 will form two arc contact bevels to increase the contact area of the heat-dissipating fins 24 and the heat-dissipating base plate 22.

Compared to the conventional technique, the present invention provides a heat sink having heat-dissipating fins of non-uniform thickness, for making the heat-dissipating fins and the heat-dissipating base plate maintain tight contact after punching forming; increasing the contact area between the heat-dissipating fins and the heat-dissipating base plate; and effectively decreasing the conductive thermal resistance therebetween. Furthermore, the performance of the heat sink on dissipating heat can be enhanced. Besides, according to the principles of heat-transfer, the shape of the heat-dissipating fins of the present invention can be trapezoid or triangle. Either of them has better performance in dissipating heat than the conventional heat sink having the heat-dissipating fins of uniform thickness.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structures.

1. A heat-dissipating fin of a heat sink, the heat sink comprising:
a heat-dissipating base plate; and
a plurality of heat-dissipating fins;
wherein the heat-dissipating base plate has a first surface contacting a heat source and a second surface on which a plurality of grooves having predetermined widths and predetermined depths are formed for inserting the heat-dissipating fins, and the heat-dissipating fins are featured in that:
the heat-dissipating fin is not uniform in thickness, and the thickness of a bottom surface of the heat-dissipating fin facing the groove is greater than the thickness of each of the other portions of the heat-dissipating fin.

2. The heat-dissipating fin of the heat sink of claim 1, wherein the shape of the heat-dissipating fin is trapezoid.

3. The heat-dissipating fin of the heat sink of claim 1, wherein the thickness of the bottom surface of the heat-dissipating fin is slightly less than the width of the groove.

4. The heat-dissipating fin of the heat sink of claim 1, wherein the heat-dissipating fin is made of the metal material selected from the group consisting of copper, copper alloys, aluminum and aluminum alloys.

5. The heat-dissipating fin of the heat sink of claim 1, wherein both sides of the heat-dissipating fin facing the groove are linear contacting bevels.

6. The heat-dissipating fin of the heat sink of claim 1, wherein both sides of the heat-dissipating fin facing the groove are arc contacting bevels.

7. A manufacturing method of a heat sink, wherein the heat sink comprises a heat-dissipating base plate, having a first surface contacting a heat source and a second surface on which a plurality of grooves having predetermined widths and predetermined depths are formed, the manufacturing method of the heat sink comprising the steps of:
providing a plurality of heat-dissipating fins which are not uniform in thickness, and the thickness of a bottom surface of the heat-dissipating fin is slightly less than the width of the groove;
inserting the heat-dissipating fins into the grooves; and
exerting pressing force onto the second surface of the heat-dissipating base plate between every two heat-dissipating fins, thereby making both sides of each of the grooves tightly attaching to both sides of each of the heat-dissipating fins.

8. The manufacturing method of the heat sink according to claim 7, wherein the way of exerting the pressing force onto both sides of each of the grooves is punching forming.

9. The manufacturing method of the heat sink according to claim 7, wherein the heat-dissipating fin is made of the metal material selected from the group consisting of copper, copper alloys, aluminum and aluminum alloys.

10. The manufacturing method of the heat sink according to claim 7, wherein the heat-dissipating base plate is made of the metal material selected from the group consisting of copper, and copper alloys.

11. The manufacturing method of the heat sink according to claim 7, wherein both sides of the heat-dissipating fin facing the groove are linear contacting bevels.

12. The manufacturing method of the heat sink according to claim 7, wherein both sides of the heat-dissipating fin facing the groove are arc contacting bevels.
